(19) United States
(12) Patent Application Publication
(10) Pub. No.: US 2003/0090404 A1
(43) Pub. Date: May 15, 2003

(54) Identical-element capacitor chain successive approximations analog-to-digital converter

(76) Inventor: Thomas Cunningham, Pasadena, CA (US)

Correspondence Address: Daniel L. Dawes, MYERS, DAWES & ANDRAS LLP, Ste 1150, 19900 MacArthur Blvd, Irvine, CA, 92612, US

(21) Appl. No.: 10/222,256

(22) Filed: Aug. 16, 2002

Related U.S. Application Data
(60) Provisional application No. 60/313,409, filed on Aug. 16, 2001.

(51) Int. Cl. H03M 1/38

(52) U.S. Cl. 341/161; 341/172

(57) ABSTRACT

This disclosure provides detailed information on a capacitor chain successive approximation analog-to-digital converter. This specific innovation will replace the binary scaled capacitor of the prior art in capacitor successive approximation analog to digital converters comprises a chainable capacitor cell where each cell in the chain is identical. This will provide for a smaller, more compact circuit, allowing better capacitor matching.

### FIELD OF INVENTION

This invention relates to successive approximation analog to digital converters.

The remainder of this contains six sections. The first provides background on analog-to-digital converters (ADC) in general, and successive approximation analog-to-digital converters (SA-ADC) in particular. The second section describes the art existing prior to the innovation. The third describes the problems associated with the prior art. The fourth presents the capacitor chain SA-ADC innovation as a solution to thee problems, and the fifth discusses the capacitor chain and its electrical operation in some detail. Finally, a summary recaps the most important points.

### BACKGROUND

Many transducers that create varying voltages or currents. This analog output will vary between a minimum and maximum value and is continuous in time. An example is a microphone that produces a continuous voltage in response to the variation in air pressure.

A digital representation of an analog signal is easier to store, manipulate, and transmit. Consequently an analog-to-digital converter (ADC) is used to convert an analog signal into its digital representation. Usually the analog signal is represented by ‘n’ digital (base 2) binary digits allowing a resolution of the analog to a value of 1/2n.

There are a large number of ADC technologies available: flash, single slope, dual slope, pipeline, and cyclic architectures. One type well suited for implementation in CMOS (Complementary Metal-Oxide Semiconductor) is the successive approximation ADC.

The technique used by a successive approximation analog to digital converter consists of comparing an unknown voltage with a series of calibrated voltages. Calibrated voltages are binary scaled where the first calibrated voltage is 1/2 the maximum voltage required to be measured and successive voltages are ½ the previous voltage (e.g. the voltages are scaled ½ Vₘₐₓ, ¼ Vₘₐₓ, ⅛ Vₘₐₓ, etc). The digital resolution of the analog signal is dependent on the number of calibrated voltages.

The reference voltages are created using a voltage divider. It is common to use a bank of binary-scaled capacitors, that is, each successive capacitor is half the value of the previous one. One end of each capacitor is connected to a common line that to goes to the comparator; the other end of each is connected to a switch that can toggle between a reference voltage and ground (0 volts).

Each capacitor forms a voltage divider between its switched end and the common node that is connected to the comparator, so when the switch is thrown from the ground to the reference voltage, the voltage on the common node increases by some fraction of the reference voltage, where the exact fraction depends upon the size of the capacitance. When the switch connected to the largest capacitor is thrown, the common node voltage increases by V_{ref}/2. Since the next largest capacitor is thrown, the common node voltage increases by V_{ref}/4. Similarly, throwing the switch connected to each successive capacitor increases the common node voltage by V_{ref}/8, V_{ref}/16, V_{ref}/32, respectively.

An AC analysis of the circuit will show that the capacitors are independent, so throwing the switch on a given capacitor increases the common node voltage by the same amount, with regard to what the common node voltage was to begin with. Therefore, throwing the switch to the second largest capacitor sends the common node voltage to ¼ V_{ref} or ¾ V_{ref}, respectively, depending on whether the common node voltage was 0 ro ½ V_{ref}, that is whether the switch to the largest capacitor connected to ground or to V_{ref}.

In order to do a conversion, all of the switches are originally set to ground so that the voltage on the common node is zero while voltage voltage to be converted is stored on its capacitor. Then the switch of each capacitor is thrown from ground to the reference voltage in turn. For each, if the comparator flips the switch is return to ground; otherwise it is left at V_{ref}. In this fashion, the voltage on the common node is successively closer to the voltage to be converted, and the state of the switches serves as a binary coded form of the digital value of the voltage, once the conversion is complete.

No disclosure herein is to be construed, as an admission that any reference cited herein is prior art against the present invention.

### BRIEF SUMMARY OF THE INVENTION

Analog to Digital Converters (ADC) are widely used to convert the value of an analog signal into an equivalent digital representation. Of the many types of ADC's, one type, a Successive Approximation Analog to Digital Converter (SA-ADC) is popular because of its flexibility and low cost. One implementation of a SA-ADC utilizes a network of capacitors and switches to generate a reference voltage. In previous implementations this network required that the capacitors be proportionally scaled. This scaling can lead to implementation problems on integrated circuits since it is difficult to fabricate capacitors with differing values.

This invention implements a SA-ADC that needs only one value for the capacitors. This alleviates the problems of fabrication where multiple values of the capacitors are utilized.

Objects and Advantages

The first object of the SA-ADC using a bank of binary-scaled capacitors requires a wide range of capacitors with values accurately scaled in powers of 2. This leads to two problems: first, it is difficult to match the capacitors accurately when their absolute size is changing so dramatically, and second, the size of the largest capacitor limits how small the ADC can be.

A capacitor is made from two plate conductors separated by an insulator. The capacitance is approximately given by the area of the plates times a property of the insulator times the dielectric constant, divided by the distance between the plates. However, the electric field in the capacitor doesn't end abruptly at the end of the plates, resulting in an additional contribution to the capacitance proportional to the perimeter of the plates. The wiring used to connect the capacitor also contributes capacitance, and structures near a capacitor, especially near the edges, can influence the capacitance. Therefore doubling the plate area of a capacitor does not necessarily double the capacitance exactly.

While edge effects and other stray capacitance contributions can be measured, it still makes it difficult to accurately match the values of capacitors of widely different sizes. For example, in a 10-bit ADC the largest capacitor capacitance value that is 512 times the smallest, and it must be exactly 512 times the value, within a part in a thousand or so. This at the limit of how closely the stray capacitances can be controlled from one manufacturing run to another. Secondly, it is poor design practice to use capacitors where the capacitance value is dominated by the stray capacitance from wiring and the edges. Since the perimeter to area ration increases as capacitance size is decreased; this implies a minimum area for the smallest capacitor in the binary series. Since the capacitor of the largest capacitor is some fixed number times that of the smallest (512 times, for the 10-bit example used previously) and since in a CMOS process the chip designer can only change the capacitor area (the plate-to-plate distance and the dielectric constant of the insulator are fixed for a given CMOS process), this implies a minimum area for the largest capacitor. In practice, the minimum area can be large: in present imager designs using column parallel ADC's, the ADC's can take up nearly as much chip area as the active imaging area.

### BRIEF DESCRIPTION OF THE DRAWINGS

FIG. 1 is an illustration of a generic successive approximation analog-to-digital converter. The voltage to be converted is compared against the sum of a set of binary-scaled voltages. Each voltage is switched in, in turn, from the largest to the smallest. If the comparator indicates that the sum is less than the voltage to be converted, then the voltage is left in and a “1” is recorded in the output; if the sum is greater than the voltage to be converted, the voltage is switched out again, and a “0” is recorded.

FIG. 2 is an abbreviated schematic of a capacitive successive approximation analog-to-digital converter of the prior art. The sum of binary weighted voltages is generated by throwing one end of successively smaller capacitors from ground to V_{ref}. The design requires a wide range of capacitor values.

FIG. 3 is an abbreviated schematic of a capacitive successive approximations analog-to-digital using a terminated chain of identical capacitor cells. The sum of binary-weighted voltages is generated by throwing the switch on the cells successively farther away from the connection to the comparator from ground to V_{ref}. Using two capacitors in parallel to get the “2C” value of capacitance, the design can be implemented using only a single capacitor value.

FIG. 4 shows the detail of a single cell, with the capacitors implemented using a single capacitor type, and with the switches implemented using field-effect transistors (FETs) as would be done in an actual CMOS design.

FIGS. 5A, 5B, 5C and 5D provide various configurations of capacitors.

FIG. 6 shows the equivalent capacitance seen looking left from node n₁ of a cell in the capacitor chain towards a chain of n cells terminated with the T₁ termination cell.

FIG. 7 shows the equivalent circuit for calculating how the cell node voltage changes when that cells switch is thrown from the ground to V_{ref}. The circuit forms a capacitive divider, dividing the voltage by 3.

FIG. 8 shows the equivalent circuit for calculating how the node voltage changes in cells along the chain, when one cell's switch is thrown from ground to V_{ref}. The node of the switched

### DESCRIPTION OF THE PREFERRED EMBODIMENT

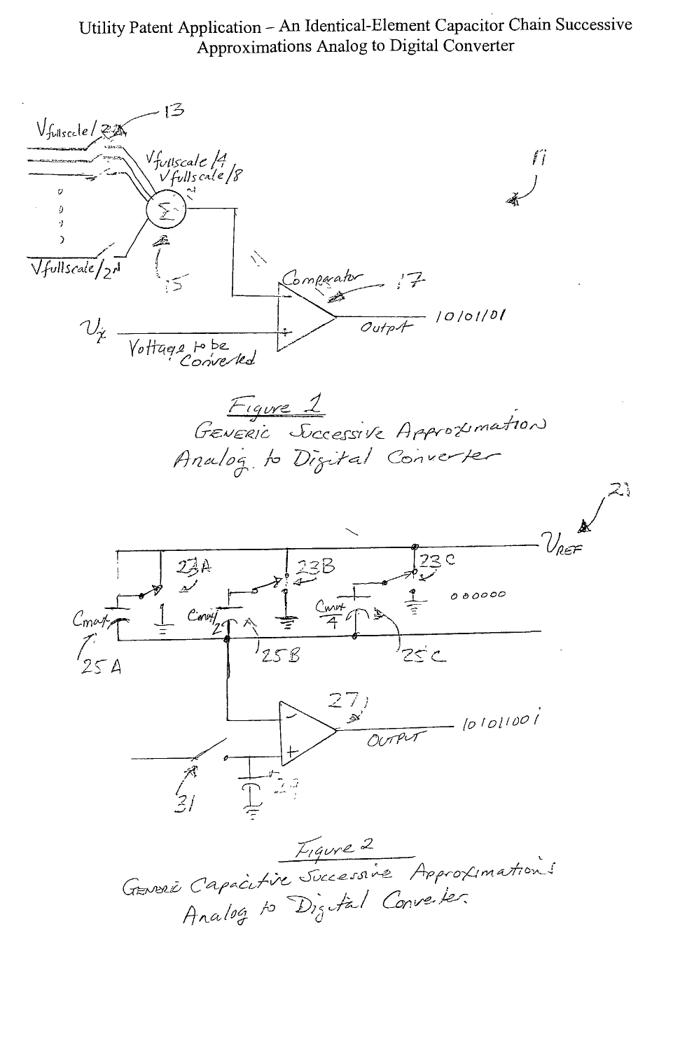

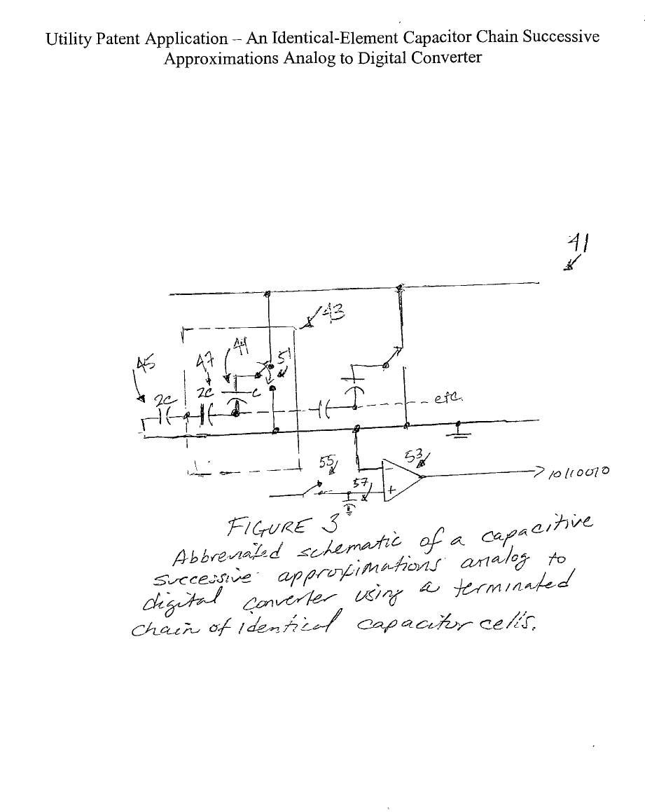

In FIG. 1, 11 a set of Calibrated voltages 13 are binary scaled where the first calibrated voltage is ½ the maximum voltage required to be measured and successive voltages are ½ the previous voltage (e.g. the voltages are scaled ½ Vmax, ¼ Vmax, ⅛ Vmax, etc). The digital resolution of the analog signal is dependent on the number of calibrated voltages. These voltages may be summed 15 and fed to a comparator 17 to be compared to the unknown voltage 19. The calibrated voltages may be created using a set of scaled capacitors (capacitor array) FIG. 221, that proportional in value, i.e. the first capacitor has a value of Cmax 25A, the second capacitor has a value of Cmax/2 25B, the third capacitor has a value of Cmax/4 25C, etc. The individual voltages may be adjusted by moving individual toggle switches 23A 23B 23C, etc from reference ground to Vmax. This reference voltage is fed to the negative terminal of the comparator 27. The unknown, voltage is fed to the positive terminal of the comparator 27. This voltage is sampled using a switch 31 combined with a capacitor 29.

The innovation is to replace the binary-scaled set of capacitors all connected to the common node going into the comparator with a chain of capacitor cells. Only one cell is connected to the comparator directly; the second cell connects to the first, the third connects to the second, etc. Each cell in the chain is identical except for special termination cells at each end of the chain.

Each cell contains two capacitors, one having twice the capacitance of the other. In practice, the large capacitor can be made from two capacitors in parallel, so that the cell actually consists of three identical capacitors, two of which are tied together. One cell is needed for each bit of ADC resolution.

This provides a solution to the two problems discussed above. First, because all of the capacitors can be identical it is much easier to match them accurately. Identical capacitors will have identical areas, identical perimeters, etc. Second, this scheme allows the total area of the capacitor bank to be much smaller. With three capacitors per cell and one cell per bit, a 10 bit ADC requires 30 capacitors. If each capacitor is minimum size, the entire bank requires 30 times the area of the minimum size capacitor. By contrast, in the prior art (FIG. 1) using a binary-scaled bank of individual capacitors, the largest capacitor is 512 times the smallest in a 10-bit ADC, and the total area taken by all capacitors is 1024 times area of a minimum size capacitor. The proposed innovation can reduce the area required by more than 30 times.

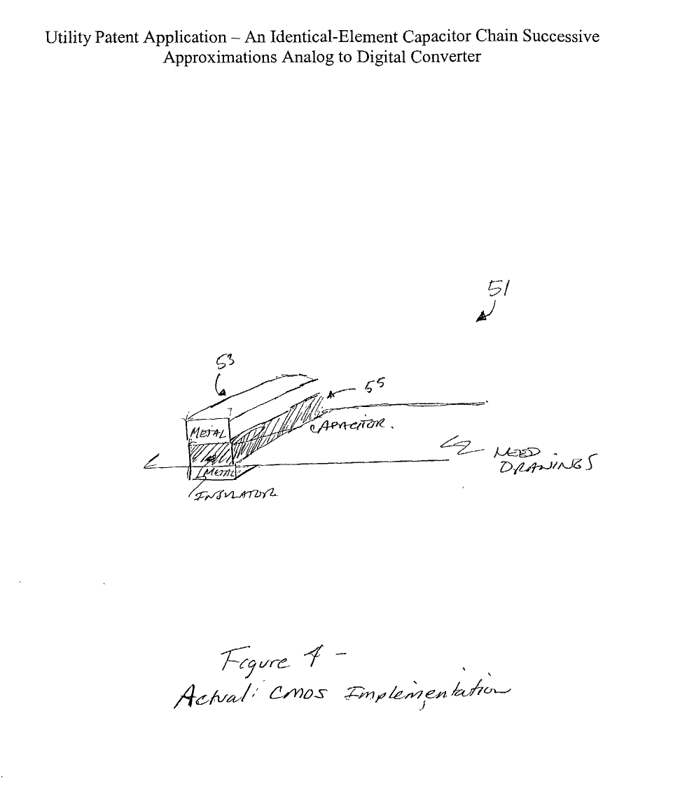

A schematic representation of the proposed successive approximation analog-to-digital converter using a chain of capacitor cells is shown in FIG. 341. Just as in the prior art, the ADC contains a comparator 53 and a capacitor 57 for the holding the voltage to be converted, with this voltage fed to one input of the comparator. However, the bank of binary-scaled capacitors for generating the voltage sum in the prior art is replaced with a chain of capacitor cells. FIG. 4 shows the detail of a single cell, with the capacitors implemented using a single capacitor type, and with the switches implemented using field-effect transistors (FETs) as would be done in an actual CMOS design.

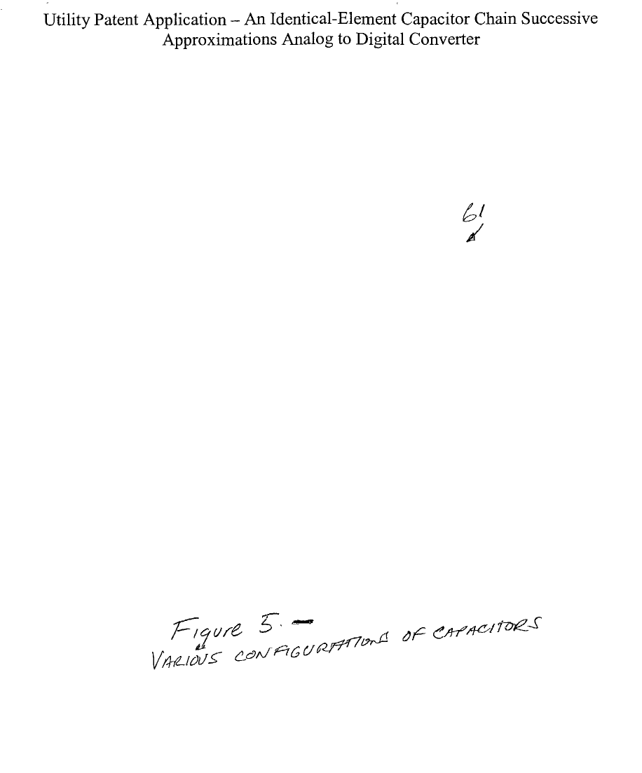

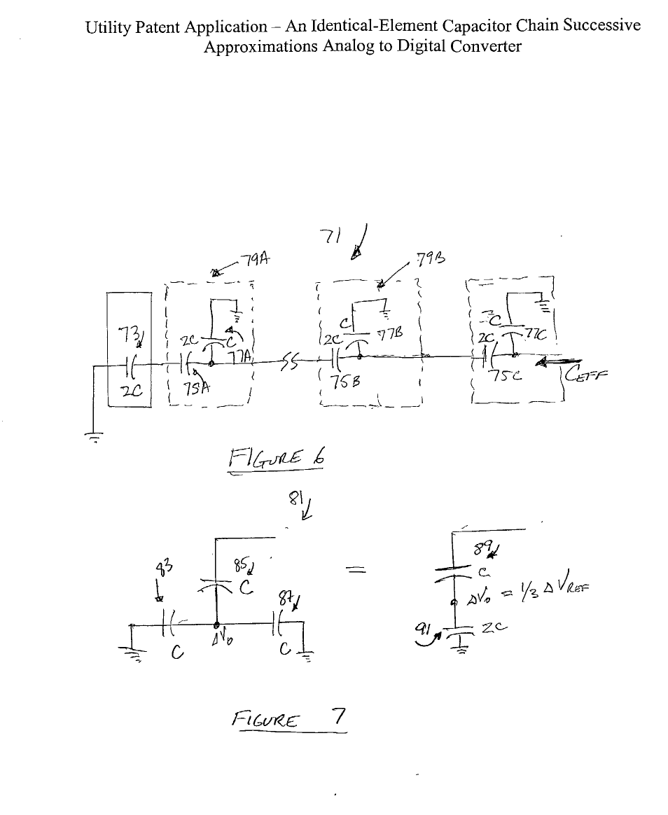

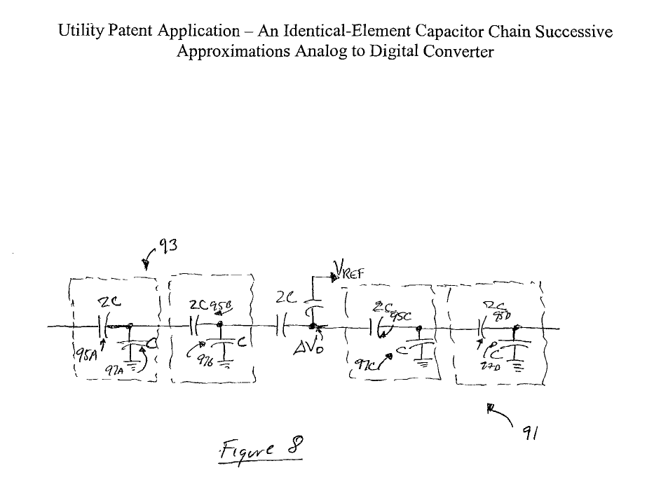

To see how the ADC functions electrically, consider first an AC analysis of the chain. In the AC sense, all voltage sources are replaced with ground, so it doesn't matter whether the switches for the cells are set to V_{ref} or ground. Consider the situation shown in FIG. 5. FIG. 5a shows the termination cell T₂ consisting of a single capacitor C. Clearly the capacitance seen looking into n₁ of this cell is simply C. Now consider the situation of FIG. 5b, where a single chain cell is combined with the T₂ termination cell. The capacitance seen looking into node n₂ of the chain cell is then 2C in series with a parallel combination of C and C.

Ceff=1/(1/2C+1/(C+C))

Ceff=1/(2/2C)

Ceff=C

Ceff=1/(1/2C+1/2C)

Now consider the situation of FIG. 5c where two chain cells are connected with the termination cell of T₂. To find the effective capacitance looking in to node n₂ of the second cell, we need to know the effective capacitance tied to node n₁ of the cell. This, however, is just the value solved for from FIG. 5b, that is, C. With the value C tied to node n₁, however, the situation of FIG. 5c reduces to that of FIG. 5b, so the effective capacitance looking into the node n₂ equal to C.

Then consider the situation shown in FIG. 671, where a series of capacitor cells are terminated with a slightly different termination cell, T₁ 79A 79B 79C. The effective capacitance looking to the left of node n₁ (but not including the capacitor in the cell itself) represents just a flipping of the same situation analyzed in FIG. 5d. Therefore the effective capacitance is again just C. With a properly terminated series of chain cells of any length connected together, each cell sees an effective capacitance of C to the right of node n₁ and C to the left of n₁. The steady-state response with respect to switching can then be analyzed by considering the equivalent circuit shown in FIG. 781. A capacitor C is connected from node n₁ to the switch. In addition, n₁ sees a capacitance to ground of C looking left and C looking right. This forms a capacitive divider, so that the change in voltage at n₁ as the switch is thrown from ground to V_{ref}.

ΔVₙ₁=(V_{ref}−0)(C/C+C+C)

ΔVₙ₁=⅓(Vref)

This voltage change is independent of the initial voltage, so the final voltage is just the sum of the initial voltage and the voltage change. This change is reversible, so that if the switch is thrown back to ground the voltage on the node returns to its original value. Throwing the switch for a given cell then simply changes that cell's node voltage by ⅓ V_{ref}.

ΔV₁=ΔV₀(½)

ΔV₁=ΔV₀(2C/2C+C+C)

ΔV₁=ΔV₀(2C/4C)

Now consider the effect that throwing a switch for a given cell has on other cells. First consider the neighboring cell to the left. For the steady state value of the effect of throwing a given switch, the capacitors connected to other switches may be considered connected to ground in the transient sense, regardless of whether they are connected to ground or to V_{ref}. The effective circuit is then that shown in FIG. 891. The capacitor from cell₀ to cell₁ together with the cell₁ capacitor to ground in effective capacitance from the remaining cells in the chain going left form a capacitive divider, so

Since the chain repeats exactly, this effect continues down the chain, so ΔV₂=½ *ΔV₁, ΔV₃=½ *ΔV₂, ΔV₄=½ *ΔV₃,etc. We have already found the effect of throwing a switch on the cell's own voltage, so in general

ΣΔVn=⅓ (ΔVref)(½N)

Where n is the distance, in cells, between the switched and measured cell.

With the exception that V_{ref} of the prior art is replaced by ⅔ V_{ref} in the innovation, the operation of the two types of SA-ADC'S is the same. Referring back to the schematic of FIG. 341, the voltage to be converted is sampled onto its capacitor that connects to one input of the comparator. All switches are in the capacitor chain are connected to ground so that the voltage to the other input of the comparator is zero. The switches are then thrown in turn, starting from the cell connected to the comparator. If after a switch is thrown, the voltage produced by the capacitor chain is greater than the value to be converted, that switch is returned to ground. If not, that switch is left connected to V_{ref}. The effect is the same as in the prior art: the operation with the most significant cell determines whether voltage to be converted is in the upper or lower half of the range. Each successive operation narrows the remaining range by a factor of two.

Summary

Replacing the bank of binary scaled capacitors in the capacitive successive approximation analog-to-digital converter of the prior art with a properly terminated chaining of capacitive divider cells will allow a significant size reduction of the ADC while promoting better capacitor matching for increased accuracy. The operation of the ADC will remain almost completely unchanged, except that the reference voltage must be scaled by 1.5 times to maintain the same input voltage range.

I claim:

1. An Analog to Digital Converter comprising:
a comparator having a positive input, a negative input, and a binary output,
a means for creating an adjustable reference voltage varying from about a maximum voltage and reference ground said means comprising a plurality of switches and capacitors,
a means for connecting said adjustable reference voltage to the negative input,
a means for sampling an unknown voltage and keeping said unknown voltage constant for a conversion period on the positive input,
wherein the binary output indicates a binary true value when the difference in voltage between said adjustable reference voltage and said unknown voltage is positive.

2. The Analog to Digital Converter as recited in claim 1, wherein said plurality of switches and capacitors comprises:
a plurality of switched capacitive cells connected in series each cell having an input terminal, a reference terminal, an input capacitor, an output capacitor, and
a toggle switch wherein said toggle switch selects between a maximum voltage and the reference ground,
a means for connecting said input capacitor between said input terminal and said reference terminal,
a means for connecting said output capacitor between said reference terminal and said toggle switch,
a sampling switch positioned between said unknown voltage and the positive input of said comparator,
a trailing capacitor between said reference terminal of the last switched capacitive cell and reference ground,
means for moving said toggle switch in each capacitive cell from reference ground to maximum voltage and detecting if the binary output of said comparator is either approximately logical true or logical false.

3. The Analog to Digital Converter as recited in claim 1, wherein said plurality of switches and capacitors comprises:
a means for connecting one pole of said sampling switch to the unknown voltage and the other pole of said sample switch to the positive input of said comparator,
a leading capacitor positioned between said input terminal of first switched capacitive cell and the reference ground,

4. A method wherein the toggle switch of each capacitive cell is thrown in succession from said first capacitive cell to said last switched capacitive cell.

5. The method of claim 4 where the output of said comparator is detected and the toggle switch is kept open if the output exceeds the unknown voltage.

6. The Analog to Digital Converter as recited in claim 2 wherein said leading capacitor, said input capacitor, said output capacitor, and said trailing capacitor comprise:
means for scaling said output capacitor and said trailing capacitor to equivalent values,
means for scaling said leading capacitor and said input capacitor to equivalent values,
means for scaling said leading capacitor to be approximately twice the value of said trailing capacitor.
